(19) United States
(12) Patent Application Publication
(10) Pub. No.: US 2025/0015772 A1
(43) Pub. Date: Jan. 9, 2025

(54) DRIVE DEVICE, OPTICAL SYSTEM AND LITHOGRAPHY APPARATUS

(71) Applicant: Carl Zeiss SMT GmbH, Oberkochen (DE)

(72) Inventors: Cornelius Richt, Aalen (DE); Oliver Herbst, Aalen (DE); Anton Montagne, KN Delft (NL)

(21) Appl. No.: 18/895,292

(22) Filed: Sep. 24, 2024

Related U.S. Application Data
(63) Continuation of application No. PCT/EP2023/058440, filed on Mar. 31, 2023.

(30) Foreign Application Priority Data
Apr. 1, 2022 (DE) 10 2022 203 255.1

(51) Int. Cl. H03F 3/45; G03F 7/00

(52) U.S. Cl. CPC H03F 3/45475; G03F 7/70266; H03F 2203/45526

(57) ABSTRACT

A drive device for driving and measuring an actuator for actuating an optical element of an optical system comprises a drive unit, a voltage measuring unit and a current measuring unit having a frequency-dependent first transfer function configured to amplify a time-dependent

### CROSS-REFERENCE TO RELATED APPLICATIONS

The present application is a continuation of, and claims benefit under 35 USC 120 to, international application No. PCT/EP2023/058440, filed Mar. 31, 2023, which claims benefit under 35 USC 119 of German Application No. 10 2022 203 255.1, filed Apr. 1, 2022. The entire disclosure of each of these applications is incorporated by reference herein.

### FIELD

The present disclosure relates to a drive device for driving and measuring an actuator of an optical system, to an optical system comprising such a drive device, and to a lithography apparatus comprising such an optical system.

### BACKGROUND

Microlithography apparatuses are known which have actuatable optical elements, such as, for example, microlens element arrays or micromirror arrays. Microlithography is used for producing microstructured component parts, such as for example integrated circuits. The microlithography process is performed using a lithography apparatus, which has an illumination system and a projection system.

Driven by the desire for ever smaller structures in the production of integrated circuits, EUV lithography apparatuses that use light with a wavelength in the range from 0.1 nm to 30 nm, such as 13.5 nm, are currently under development. Since most materials absorb light of this wavelength, EUV lithography apparatuses typically use reflective optics, that is to say mirrors, instead of—as previously—refractive optics, that is to say lenses.

The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate. The imaging of the mask on the substrate can be improved using actuatable optical elements. By way of example, wavefront aberrations during exposure, which result in magnified and/or blurred imaging, can be compensated for.

Such correction via the optical element can involve detection of the wavefront and signal processing in order to determine a respective position of an optical element which enables the wavefront to be corrected as desired. In the last step, the drive signal for a respective optical element is amplified and output to the actuator of the optical element.

By way of example, a PMN actuator (PMN; lead magnesium niobate) can be used as actuator. A PMN actuator can help enable distance positioning in the sub-micrometre range or sub-nanometre range. In this case, the actuator, having actuator elements stacked one on top of another, can experience a force that causes a specific linear expansion as a result of a DC voltage being applied. The position set by way of the DC voltage (DC; Direct Current) can be adversely influenced by external electromechanical crosstalk at the fundamentally arising resonance points of the actuator driven by the DC voltage. Owing to this electromechanical crosstalk, precise positioning might no longer able to be set in a stable manner. In this case, the mechanical resonances may be all the greater the higher the applied DC voltage. The resonance points may also change in the long term, for example as a result of temperature drift or as a result of adhesive drift if the mechanical linking of the adhesive material changes, or as a result of hysteresis or ageing. For example, an impedance measurement could be helpful in this context.

However, conventional impedance measuring devices are often too cost-intensive and furthermore do not have an inline capability, that is to say that they are regularly not able to be used in a lithography apparatus. Furthermore, integrated impedance measuring bridges, which are usually designed for excessively high impedance values, might not to be suitable for the present application in a lithography apparatus since the impedance value range of interest here encompasses a plurality of orders of magnitude and the range of interest is only a fraction of the total range.

It is also known practice to drive the actuators of a lithography apparatus via a respective drive signal which has a low-frequency drive component for driving the actuator and a higher-frequency measurement signal component for measuring the actuator. Conventionally, such a drive signal is amplified with a gain that is uniform over the frequency via an output stage and is applied to the actuator as drive voltage. Such a conventional output stage brings about a uniform gain over all frequency ranges and hence a uniform resolution. If a high gain is chosen for the gain by way of the output stage, this high gain can cause a deterioration in the resolution for measuring the impedance of the actuator. However, if a low gain is chosen, the latter might not be sufficient in applications for driving the actuator.

### SUMMARY

The present disclosure seeks to improve the driving of an actuator of an optical system.

In accordance with a first aspect, a drive device for driving and measuring an actuator of an optical system is proposed. The drive device comprises:
a drive unit having a frequency-dependent first transfer function which is configured to amplify a time-dependent AC voltage signal with at least a first frequency range and a second frequency range to form a drive voltage for the actuator, in such a way that the first frequency range experiences a higher gain vis-à-vis the second frequency range by a specific factor,
a voltage measuring unit for providing a measurement voltage, which is configured to convolve, in the time domain, a time-dependent voltage of the actuator with a second transfer function that is based on an inverse of the first transfer function and to subsequently measure the time-dependent voltage for the provision of the measurement voltage, and
a current measuring unit for providing a measurement current, which is configured to convolve, in the time domain, a time-dependent current of the actuator with a third transfer function that is based on an inverse of the first transfer function and to subsequently measure the time-dependent current for the provision of the measurement current.

The present drive device can help enable high gain in the first frequency range for driving the actuator and, at the same time, a high resolution in the second frequency range for measuring the actuator, such as for measuring the impedance of the actuator.

In this case, the component of the drive voltage in the first frequency range serves to drive the actuator, for example the control of the deflection thereof. In the process, the first frequency range experiences a higher gain vis-à-vis the second frequency range in order to suitably drive the actuator. Prior to the respective measurement, that is to say prior to the voltage measurement and the current measurement, the first frequency range is damped and the second frequency range is amplified so that a high resolution for measuring the actuator is provided in the second frequency range.

The present drive device may also be referred to as a frequency-dependent amplifier stage for driving an actuator, with an integrated current measurement and voltage measurement.

As a result of providing the measurement voltage and the measurement current of the actuator, the present drive device can help enable a quick and in line-capable determination of the impedance behaviour of the actuator, such as an impedance determination of the actuator installed in the lithography apparatus.

On the basis of the determined impedance behaviour of the actuator, suitable remedies or countermeasures, such as an active inline calibration or inline damping, can also be implemented via the drive signal.

For example, the actuator is a capacitive actuator, for example a PMN actuator (PMN; lead magnesium niobate) or a PZT actuator (PZT; lead zirconate titanate) or a LiNbO3 actuator (lithium niobate). The actuator is configured, for example, to actuate an optical element of the optical system. Examples of such an optical element include lens elements, mirrors and adaptive mirrors.

The optical system can be a projection optical unit of the lithography apparatus or projection exposure apparatus. However, the optical system may also be an illumination system. The projection exposure apparatus may be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light of between 30 nm and 250 nm.

According to an embodiment, the drive device further comprises a determination unit which is coupled to the voltage measuring unit and to the current measuring unit. The determination unit is configured to determine an impedance of the actuator on the basis of the provided measurement voltage and the provided measurement current. For example, this embodiment of the drive device can also be referred to as a frequency-dependent amplifier stage for driving and measuring the impedance of an actuator.

According to an embodiment, the first frequency range is located between 0 Hz and 1 kHz, such as between 0 Hz and 500 Hz, for example between 0 Hz and 300 Hz.

According to an embodiment, the second frequency range is located between 5 kHz and 100 kHz, such as between 10 kHz and 100 kHz, for example between 10 kHz and 60 KHz.

According to an embodiment, the specific factor is between 100 and 2000, such as between 500 and 1500, for example between 800 and 1200.

According to an embodiment, the drive unit comprises an amplifier circuit, for example a differential amplifier.

According to an embodiment, the amplifier circuit of the drive unit comprises an input node for feeding the AC voltage signal, an output node for providing the drive voltage for the actuator and an operational amplifier coupled between the input node and the output node. Here, for the purpose of providing the transfer function, a first circuit can be coupled to the input node, to a negative supply voltage of the drive device and to the non-inverting input of the operational amplifier and a second circuit is coupled to the inverting input of the operational amplifier, to earth and to the output node.

According to an embodiment, the first circuit and the second circuit each comprise a resistance circuit to adjust the gain in the first frequency range and, to adjust the gain in the second frequency range, each circuit additionally comprises a frequency-dependently connectable circuit comprising a frequency-dependent component part and a resistor. The frequency-dependently connectable circuit comprising the frequency-dependent component part and the resistor is for example in the form of a capacitor and the resistor connected in series.

In this case, the capacitance of the capacitor is chosen, for example, in such a way that the capacitor is conductive at the frequencies in the second frequency range and hence the connectable circuit is frequency-dependently connected at the frequencies in the second frequency range. The respective frequency range may also be referred to as a frequency band.

According to an embodiment, the voltage measuring unit comprises an amplifier circuit, such as a differential amplifier.

According to an embodiment, the amplifier circuit of the voltage measuring unit comprises an input node which is coupled to the output node of the amplifier circuit of the drive unit and which serves to receive the time-dependent voltage of the actuator, an output node for providing the measurement voltage and an operational amplifier coupled between the input node and the output node. Here, to provide the second transfer function, a first circuit is coupled to the output node, to the negative supply voltage of the drive device and to the inverting input of the operational amplifier and a second circuit is coupled to the input node, to the non-inverting input of the operational amplifier and to earth.

According to an embodiment, the first circuit and the second circuit each comprise a resistance circuit to provide the component of the second transfer function in the first frequency range and, to provide the component of the second transfer function in the second frequency range, each circuit additionally comprises a frequency-dependently connectable circuit comprising a frequency-dependent component part and a resistor.

By way of example, the connectable circuit is in the form of a capacitor and a resistor connected in series. In this case, the capacitance of the capacitor can be chosen in such a way that the capacitor is conductive at the frequencies in the second frequency range and hence the connectable circuit is frequency-dependently connected at the frequencies in the second frequency range.

According to an embodiment, the second circuit of the amplifier circuit of the drive unit and the second circuit of the amplifier circuit of the voltage measuring unit are formed by a single circuit. This can save component parts and hence space in the optical system.

The voltage measuring units may also be connected to different channels or different actuators by way of a multiplexer. Although it might not be possible for all actuators to be measured simultaneously in that case, fewer circuits can be used.

In accordance with a second aspect, an optical system comprising a number of actuatable optical elements is proposed, wherein each of the actuatable optical elements of the number is assigned an actuator, wherein each actuator is assigned a drive device for driving the actuator in accordance with the first aspect or in accordance with one of the embodiments of the first aspect.

The optical system comprises, for example, a micromirror array and/or a microlens element array having a multiplicity of optical elements that are actuatable independently of one another.

In embodiments, groups of actuators can be defined, wherein all actuators of a group are assigned the same drive device.

According to an embodiment, the optical system is in the form of an illumination optical unit or in the form of a projection optical unit of a lithography apparatus.

According to an embodiment, the optical system has a vacuum housing, in which the actuatable optical elements, the assigned actuators and the drive device are arranged.

In accordance with a third aspect, a lithography apparatus is proposed, which has an optical system in accordance with the second aspect or in accordance with one of the embodiments of the second aspect.

The lithography apparatus is for example an EUV lithography apparatus, the working light of which is in a wavelength range of 0.1 nm to 30 nm, or a DUV lithography apparatus, the working light of which is in a wavelength range of 30 nm to 250 nm.

“A” or “an” in the present case should not necessarily be understood to be restrictive to exactly one element. Rather, a plurality of elements, such as for example two, three or more, may also be provided. Any other numeral used here should also not be understood to the effect that there is a restriction to exactly the stated number of elements. Rather, unless indicated otherwise, numerical deviations upwards and downwards are possible.

Further possible implementations of the disclosure also comprise not explicitly mentioned combinations of features or embodiments that are described above or below with respect to the exemplary embodiments. In this case, a person skilled in the art will also add individual aspects as improvements or supplementations to the respective basic form of the disclosure.

Further configurations and aspects of the disclosure are the subject matter of the dependent claims and also of the exemplary embodiments of the disclosure described hereinafter. The disclosure is explained in greater detail below on the basis of preferred embodiments with reference to the appended figures.

### BRIEF DESCRIPTION OF THE DRAWINGS

FIG. 1 shows a schematic meridional section of a projection exposure apparatus for an EUV projection lithography;

FIG. 2 shows a schematic illustration of an embodiment of an optical system;

FIG. 3 shows a schematic block diagram of an embodiment of a drive device for driving and measuring an actuator for actuating an optical element in an optical system;

FIG. 4 shows the block diagram of FIG. 3 with plotted transfer functions; and

FIG. 5 shows a schematic block diagram with embodiments of the drive unit and the voltage measuring unit of a drive device for driving and measuring an actuator for actuating an optical element in an optical system.

### DETAILED DESCRIPTION

Unless indicated otherwise, elements that are identical or functionally identical have been given the same reference signs in the figures. It should also be noted that the illustrations in the figures are not necessarily true to scale.

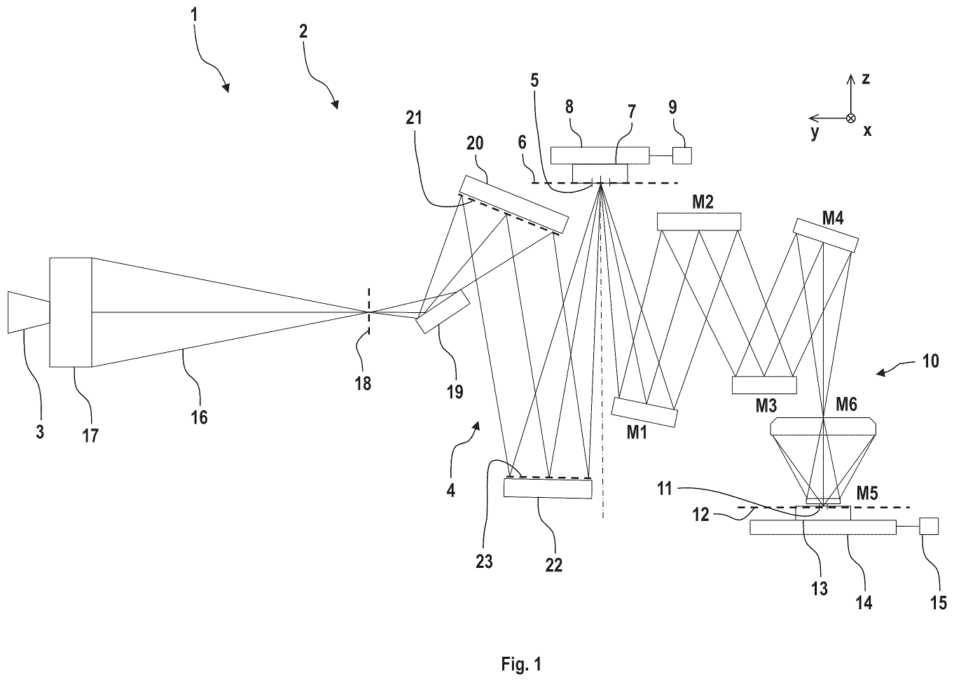

FIG. 1 shows an embodiment of a projection exposure apparatus 1 (lithography apparatus), such as an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, such as in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs along the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, such as along the y-direction y. The displacement, firstly, of the reticle 7 by way of the reticle displacement drive 9 and, secondly, of the wafer 13 by way of the wafer displacement drive 15 may be implemented so as to be mutually synchronized.

The light source 3 is an EUV radiation source. The light source 3 emits for example EUV radiation 16, which is also referred to below as used radiation, illumination radiation or illumination light. For example, the used radiation 16 has a wavelength in the range between 5 nm and 30 nm. The light source 3 may be a plasma source, for example an LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emerging from the light source 3 is focused by a collector 17. The collector 17 may be a collector with one or more ellipsoidal and/or hyperboloidal reflection surfaces. The at least one reflection surface of the collector 17 may be impinged upon by the illumination radiation 16 with grazing incidence (abbreviated as: GI), that is to say with angles of incidence greater than 45°, or with normal incidence (abbreviated as: NI), that is to say with angles of incidence less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. Alternatively or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, such as rectangular facets or as facets with an arcuate edge contour or an edge contour of part of a circle. The first facets 21 can be embodied as plane facets or, alternatively, as convexly or concavely curved facets.

As known for example from DE 10 2008 009 600 A1, the first facets 21 themselves can also be composed in each case of a multiplicity of individual mirrors, such as a multiplicity of micromirrors. For example, the first facet mirror 20 can be embodied as a microelectromechanical system (MEMS system). For details, reference is made to DE 10 2008 009 600 A1.

Between the collector 17 and the deflection mirror 19, the illumination radiation 16 travels horizontally, that is to say along the y-direction y.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 may have plane reflection surfaces or alternatively reflection surfaces with convex or concave curvature.

The illumination optical unit 4 consequently forms a doubly faceted system. This fundamental principle is also referred to as a fly's eye condenser (or integrator.

It can be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

In an embodiment, not shown, of the illumination optical unit 4, a transfer optical unit contributing such as to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit can comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In an embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are similarly possible. The projection optical unit 10 is a twice-obscured optical unit. The penultimate mirror M5 and the last mirror M6 each have a passage opening for the illumination radiation 16. The projection optical unit 10 has an image-side numerical aperture that is greater than 0.5 and may also be greater than 0.6, and may be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, such as with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may have an anamorphic form. It can have different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, that is to say in a direction perpendicular to the scanning direction.

The projection optical unit 10 leads to a reduction in size of 8:1 in the y-direction y, that is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 can be as homogeneous as possible. It can have a uniformity error of less than 2%. The field uniformity can be achieved by way of the overlay of different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, for example the subset of the second facets 23, which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and for example of the entrance pupil of the projection optical unit 10 are described below.

The projection optical unit 10 may have a homocentric entrance pupil. The latter can be accessible. It can also be inaccessible.

The entrance pupil of the projection optical unit 10 frequently cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the spacing of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, such as an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted in relation to an arrangement plane defined by the deflection mirror 19. The first facet mirror 20 is arranged so as to be tilted with respect to an arrangement plane defined by the second facet mirror 22.

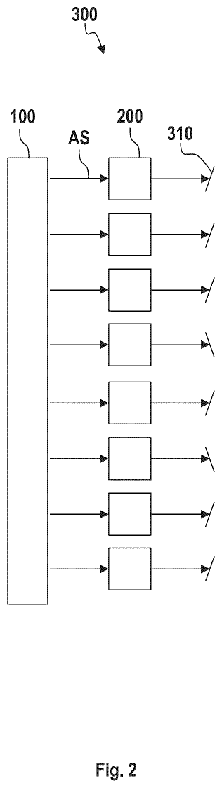

FIG. 2 shows a schematic illustration of an embodiment of an optical system 300 for a lithography apparatus or projection exposure apparatus 1, as shown in FIG. 1 for example. Additionally, the optical system 300 of FIG. 2 may also be used in a DUV lithography apparatus for example.

The optical system 300 of FIG. 2 has a plurality of actuatable optical elements 310. The optical system 300 is designed here as a micromirror array, wherein the optical elements 310 are micromirrors. Each micromirror 310 is actuatable via an assigned actuator 200. By way of example, a respective micromirror 310 can be tilted about two axes and/or displaced in one, two, or three spatial axes via the assigned actuator 200. The reference signs only of the topmost row of these elements are depicted, for reasons of clarity.

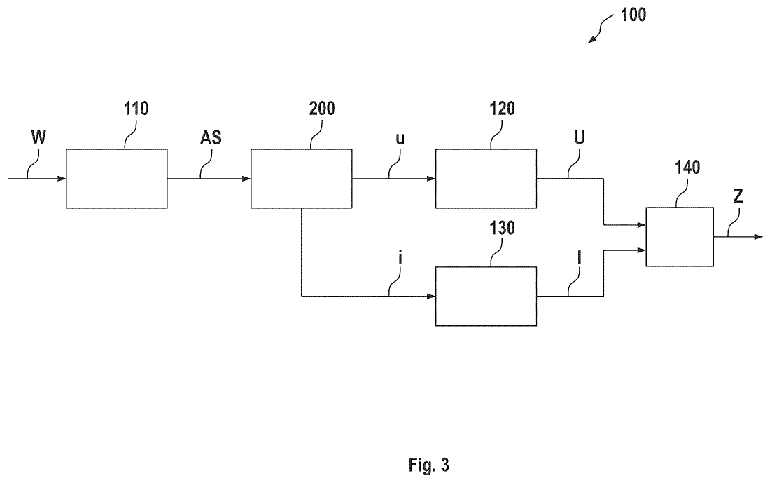

The drive device 100 drives the respective actuator 200, for example with a drive voltage AS. This sets a position of the respective micromirror 310. The drive device 100 is described with reference to FIGS. 3 to 5 for example.

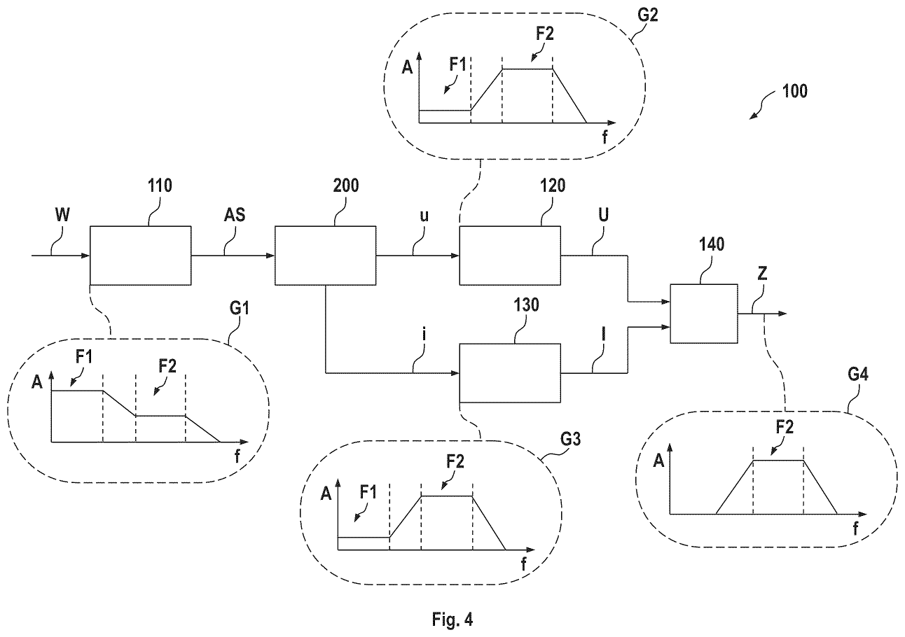

FIG. 3 illustrates a schematic block diagram of an embodiment of a drive device 100 for driving and measuring an actuator 200 for actuating an optical element 310 in an optical system 300. To this end, FIG. 4 shows the block diagram of FIG. 3 with plotted transfer functions G1-G4.

The drive device 100 according to FIG. 3 and FIG. 4 comprises a drive unit 110 for driving the actuator 200, a voltage measuring unit 120 coupled to the actuator 200, a current measuring unit 130 coupled to the actuator 200 and a determination unit 140 coupled to the voltage measuring unit 120 and to the current measuring unit 130.

The drive unit 110 has a frequency-dependent first transfer function G1 (see FIG. 4) which is configured to amplify a time-dependent AC voltage signal W with at least a first frequency range F1 and a second frequency range F2 to form a drive signal AS for the actuator 200, in such a way that the first frequency range F1 experiences a higher gain vis-à-vis the second frequency range F2 by a specific factor. As shown in exemplary fashion in FIG. 4, the first transfer function G1 has a first frequency range F1 with lower frequencies and a second frequency range F2 with higher frequencies. By way of example, the first frequency range is located between 0 Hz and 1 kHz, such as between 0 Hz and 500 Hz, for example between 0 Hz and 300 Hz. The second frequency range F2 can be located between 5 kHz and 100 kHz, such as between 10 kHz and 100 kHz, for example between 10 kHz and 60 kHz. The specific gain factor can be between 100 and 2000, such as between 500 and 1500, for example between 800 and 1200.

The voltage measuring unit 120 is configured to convolve, in the time domain, a time-dependent voltage u of the actuator 200 with a second transfer function G2 that is based on an inverse of the first transfer function G1 and to subsequently measure the time-dependent voltage for the provision of the measurement voltage U. To this end, FIG. 4 shows the second transfer function G2 of the voltage measuring unit 120, the second transfer function being based on an inverse of the first transfer function G1, as the comparison between the transfer functions G2 and G1 indicates. As the comparison of the transfer functions G1 and G2 in FIG. 4 illustrates, the first transfer function G1 brings about a high gain in the frequency range F1 whereas the second transfer function G2 brings about a low gain in the first frequency range F1. By contrast, the first transfer function G1 brings about a low gain in the second frequency range F2, whereas the second transfer function G2 brings about a higher gain in the second frequency range F2.

The component of the drive signal AS in the first frequency range F1 serves to drive the actuator 200. Consequently, the first frequency range F1 experiences a high gain in order to be able to suitably drive the actuator 200. Prior to the respective measurement, that is to say prior to the voltage measurement and the current measurement, the first frequency range F1 is damped and the second frequency range F2 is amplified so that a high resolution for measuring the actuator 200 is provided in the second frequency range F2.

In this case, the second transfer function G2 causes the provision of a high resolution in the second frequency range F2, which is of interest for the measurement, and hence allows high accuracy to be provided.

The current measuring unit 130 is configured to convolve, in the time domain, a time-dependent current i of the actuator 200 with a third transfer function G3 that is based on an inverse of the first transfer function G1 and to subsequently measure the time-dependent current for the provision of a measurement current I. The convolution in the time domain corresponds to a multiplication in the frequency range.

To this end, FIG. 4 shows the third transfer function G3. In a manner similar or equivalent to the second transfer function G2, the third transfer function G3 brings about a low gain in the first frequency range F1 and a higher gain in the second frequency range F2.

The determination device 140 which is coupled to the voltage measuring unit 120 and to the current measuring unit 130 is configured to determine an impedance Z or impedance behaviour of the actuator 200 on the basis of the provided measurement voltage U and the provided measurement current I.

To this end, the transfer function G4 for the impedance Z of the actuator 200 according to FIG. 4 exhibits the high resolution in the second frequency band F2, which may also be referred to as the measurement frequency band.

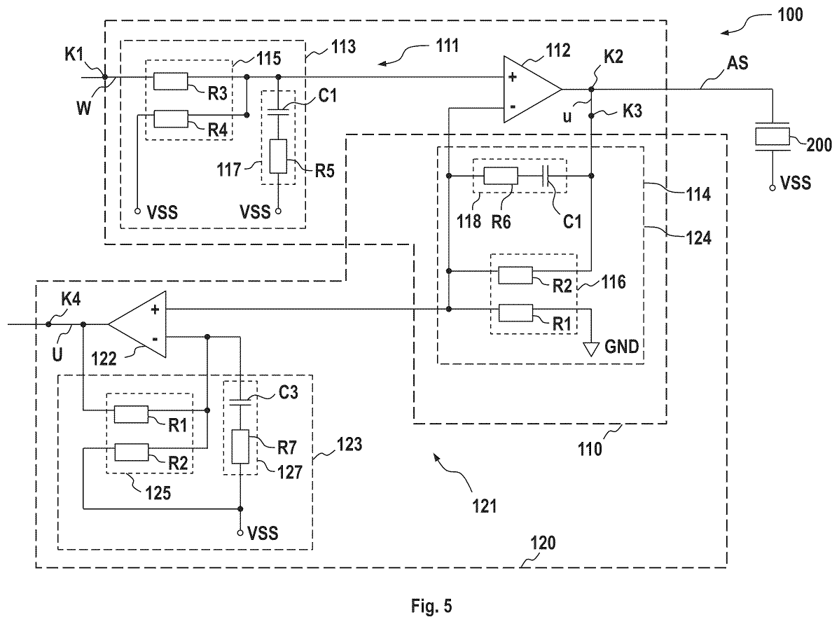

Furthermore, FIG. 5 shows a schematic block diagram with embodiments of the drive unit 110 and the voltage measuring unit 120 of a drive device 100 for driving and measuring an actuator 200 for actuating an optical element 310 in an optical system 300. An example of the drive device 100 is illustrated in FIGS. 3 and 4.

The drive unit 110 in FIG. 5 comprises an amplifier circuit 111, such as a differential amplifier.

The amplifier circuit 111 of the drive unit 110 comprises an input node K1 for feeding the AC voltage signal W (see also FIG. 3 and FIG. 4), an output node K2 for providing the drive voltage AS for the actuator 200 (see also FIGS. 2 to 4) and an operational amplifier 112 coupled between the input node K1 and the output node K2. For the purpose of providing the first transfer function G1 (see FIG. 4), a first circuit 113 is coupled to the input node K1, to a negative supply voltage VSS of the drive device 100 and to the non-inverting input of the operational amplifier 112 and a second circuit 114 is coupled to the inverting input of the operational amplifier 112, to earth GND and to the output node K2.

The first circuit 113 and the second circuit 114 each have a resistance circuit 115, 116 to adjust the gain in the first frequency range F1 and, to adjust the gain in the second frequency range F2 in accordance with the first transfer function G1, each circuit additionally has a frequency-dependent, connectable circuit 117, 118 comprising a frequency-dependent component part C1, C2 and a resistor R5, R6.

The resistance circuit 115 of the first circuit 113 comprises a resistor R3 which is connected between the input node K1 and the non-inverting input of the operational amplifier 112, and a resistor R4, which is coupled between the negative supply voltage VSS and the non-inverting input of the operational amplifier 112. Further, the connectable circuit 117 of the first circuit 113 comprises a capacitor C1 and a resistor R5 connected in series. In this case, the capacitance of the capacitor C1 is chosen in such a way that the capacitor C1 is conductive only at the frequencies in the second frequency range F2 and hence the circuit 117 is frequency-dependently connected at the frequencies in the second frequency range F2.

The resistance circuit 116 of the second circuit 114 comprises a resistor R1 which is connected between earth GND and the inverting input of the operational amplifier 112 and a resistor R2 which is connected between the inverting input of the operational amplifier 112 and the output node K2. The connectable circuit 118 of the second circuit 114 has a capacitor C2 and a resistor R6 connected in series.

The connectable circuit 118 has an equivalent functionality to the connectable circuit 117. In this case, the capacitance of the capacitor C2 is chosen in such a way that the capacitor C2 is only conductive at the frequencies in the second frequency range and hence the circuit 118 is frequency-dependently connected at the frequencies in the second frequency range.

This completes the detailed description of the drive unit 110 according to FIG. 5. Attention is now drawn to the detailed description of the voltage measuring unit 120 according to FIG. 5. The voltage measuring unit 120 in FIG. 5 comprises an amplifier circuit 121, such as a differential amplifier.

The amplifier circuit 121 of the voltage measuring unit 120 comprises an input node K3 which is coupled to the output node K2 of the amplifier circuit 111 of the drive unit 110 and which serves to receive the time-dependent voltage u of the actuator 200, an output node K4 for providing the measurement voltage U and an operational amplifier 122 coupled between the input node K3 and the output node K4. To provide the second transfer function G2, a first circuit 123 is coupled to the output node K4, to the negative supply voltage VSS of the drive device 100 and to the inverting input of the operational amplifier 122 and a second circuit 124 is coupled to the input node K3, to the non-inverting input of the operational amplifier 122 and to earth GND. In the embodiment according to FIG. 5, the second circuit 114 of the amplifier circuit 111 of the drive unit 110 and the second circuit 124 of the amplifier circuit 121 of the voltage measuring unit 120 are formed by a single circuit, that is to say they are identical. This can save components and, for example, space in the optical system 300.

As shown in FIG. 5, the first circuit 123 and the second circuit 124 of the amplifier circuit 121 of the voltage measuring unit 120 each have a resistance circuit 125, 116 to provide the part of the second transfer function G2 in the first frequency range F1 and, to provide the part of the second transfer function G2 in the second frequency range F2, the circuits each additionally have a frequency-dependably connectable circuit 127, 118.

Since the second circuit 124 of the voltage measuring unit 120 corresponds to the second circuit 114 of the drive unit 110, only the first circuit 123 of the amplifier circuit 121 of the voltage measuring unit 120 is described in detail below in order to avoid repetition. The first circuit 123 has a resistance circuit 125 which comprises a resistor R1 coupled between the output node K4 and the inverting input of the operational amplifier 122 and a resistor R2 coupled between the inverting input of the operational amplifier 122 and the negative supply voltage VSS. The resistance values of the resistors R1, R2 of the resistance circuit 116 and the resistance values of the resistors R1, R2 of the resistance circuit 125 can be the same or differ, depending on the application.

The connectable circuit 127 of the first circuit 123 comprises a capacitor C3 and a resistor R7 connected in series between the inverting input of the operational amplifier 122 and the negative supply voltage VSS. In this case, the capacitance of the capacitor C3 is chosen in such a way that the capacitor C3 is only conductive at the frequencies in the second frequency range F2.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Drive device
110 Drive unit
111 Differential amplifier
112 Operational amplifier
113 First circuit
114 Second circuit
115 Resistance circuit
116 Resistance circuit
117 Connectable circuit
118 Connectable circuit
120 Voltage measuring unit
121 Differential amplifier
122 Operational amplifier
123 First circuit
124 Second circuit
125 Resistance circuit
127 Connectable circuit
130 Current measuring unit
200 Actuator
300 Optical system
310 Optical element
A Amplitude
AS Drive voltage
C1 Capacitor
C2 Capacitor
C3 Capacitor
f Frequency
F1 First frequency range
F2 Second frequency range
G1 Transfer function
G2 Transfer function
G3 Transfer function
G4 Transfer function
GND Earth
I Measurement current
i Current of the actuator
K1 Input node
K2 Output node
K3 Input node
K4 Output node
M1 Mirror
M2 Mirror
M3 Mirror
M4 Mirror
M5 Mirror
M6 Mirror
R1 Resistor
R2 Resistor
R3 Resistor
R4 Resistor
R5 Resistor
R6 Resistor
R7 Resistor
U Measurement voltage
u Voltage of the actuator
VSS Negative supply voltage
W AC voltage signal
Z Impedance

What is claimed is:

1. A drive device configured to drive and measure an actuator configured to actuate an optical element of an optical system, the drive device comprising:
a drive unit comprising a frequency-dependent first transfer function configured to amplify a time-dependent AC voltage signal comprising a first frequency range and a second frequency range to provide a drive voltage for the actuator so that the first frequency range experiences a higher gain relative to the second frequency range by a factor;
a voltage measuring unit configured to convolve, in a time domain, a time-dependent voltage of the actuator with a second transfer function that is based on an inverse of the first transfer function and to subsequently measure the time-dependent voltage to provide a measurement voltage; and
a current measuring unit configured to convolve, in the time domain, a time-dependent current of the actuator with a third transfer function that is based on an inverse of the first transfer function and to subsequently measure the time-dependent current to provide a measurement current.

2. The drive device of claim 1, further comprising a determination unit coupled to the voltage measuring unit and to the current measuring unit, wherein the determination unit is configured to determine an impedance of the actuator based on the measurement voltage and the measurement current.

3. The drive device of claim 1, wherein the first frequency range is between 0 Hz and 1 kHz.

4. The drive device of claim 3, wherein the second frequency range is between 5 kHz and 100 kHz.

5. The drive device of claim 1, wherein the second frequency range is between 5 kHz and 100 kHz.

6. The drive device of claim 1, wherein the factor is between 100 and 2000.

7. The drive device of claim 1, wherein the drive unit comprises an amplifier circuit.

8. The drive device of claim 7, wherein the amplifier circuit comprises:
an input node configured to feed the time-dependent AC voltage signal;
an output node configured to provide the drive voltage;
an operational amplifier coupled between the input and output nodes;
a first circuit coupled to the input node, to a negative supply voltage of the drive device, and to the non-inverting input of the operational amplifier; and
a second circuit coupled to the inverting input of the operational amplifier, to earth, and to the output node.

9. The drive device of claim 8, wherein the first circuit and the second circuit each comprises:
a resistance circuit to adjust the gain in the first frequency range and to adjust the gain in the second frequency range;
a frequency-dependently connectable circuit comprising a frequency-dependent component part and a resistor.

10. The drive device of claim 1, wherein the drive unit comprises a differential amplifier.

11. The drive device of claim 1, wherein the voltage measuring unit comprises an amplifier circuit.

12. The drive device of claim 11, wherein the amplifier circuit comprises:
an input node configured to receive the time-dependent voltage of the actuator;
an output node configured to provide the measurement voltage; and
an operational amplifier coupled between the input node and the output node
a first circuit coupled to the output node, to the negative supply voltage and to the inverting input; and
a second circuit coupled to the input node, to the non-inverting input of the operational amplifier and to earth.

13. The drive device of claim 12, wherein the first circuit and the second circuit each comprises:
a resistance circuit configured to provide the component of the second transfer function in the first frequency range and to provide the component of the second transfer function in the second frequency range; and
a frequency-dependently connectable circuit comprising a frequency-dependent component part and a resistor.

14. The drive device of claim 12, wherein:
the drive unit comprises an amplifier circuit, comprising:
an input node configured to feed the time-dependent AC voltage signal;
an output node configured to provide the drive voltage;
an operational amplifier coupled between the input and output nodes;
a first circuit coupled to the input node, to a negative supply voltage of the drive device, and to the non-inverting input of the operational amplifier; and
a second circuit coupled to the inverting input of the operational amplifier, to earth, and to the output node; and
a single circuit comprises both the second circuit of the amplifier circuit of the drive unit and the second circuit of the amplifier circuit of the voltage measuring unit.

15. The drive device of claim 1, wherein the voltage measuring unit comprises a differential amplifier.

16. The drive device of claim 1, wherein the drive unit comprises a first amplifier circuit, and the voltage measuring unit comprises a second amplifier circuit.

17. An optical system, comprising:
a plurality of actuatable optical elements;
a plurality of actuators, each actuator assigned to a corresponding optical element; and
a plurality of drive devices according to claim 1, each drive device assigned to a corresponding actuator.

18. The optical system of claim 17, wherein the optical system comprises a member selected from the group consisting of a lithography illumination optical unit and a lithography projection optical unit.

19. An apparatus, comprising:
an illumination optical unit; and
a projection optical unit,
wherein the apparatus is a lithography apparatus, and at least one member selected from the group consisting of the illumination optical unit and the projection optical unit comprises a drive device according to claim 1.

20. The apparatus of claim 19, wherein the apparatus comprises a member selected from the group consisting of an EUV lithography apparatus and a DUV lithography apparatus.
